(19) United States
(12) Patent Application Publication
(10) Pub. No.: US 2008/0160458 A1
(43) Pub. Date: Jul. 3, 2008

(54) Lithographic device manufacturing method, lithographic cell, and computer program product

(75) Inventors: Koen Van Ingen Schenau, Veldhoven (NL); Wendy Fransisca Johanna Gehoel-Van Ansem, Westerhoven (NL); Johannes Anna Quaedackers, Veldhoven (NL); Patrick Wong, Schilde (BE)

Correspondence Address: PILLSBURY WINTHROP SHAW PITTMAN, LLP, P.O. BOX 10500, MCLEAN, VA, 22102, US

(73) Assignee: ASML NETHERLANDS B.V., Veldhoven (NL)

(21) Appl. No.: 12/000,190

(22) Filed: Dec. 10, 2007

Related U.S. Application Data
(60) Provisional application No. 60/874,276, filed on Dec. 12, 2006.

(51) Int. Cl. G03F 7/26

(52) U.S. Cl. 430/322; 355/53

(57) ABSTRACT

A double patterning process for printing dense lines is provided. In a first step, a first semi dense pattern of lines is printed in a first resist material layer overlaying a substrate provided with a bottom anti-reflection coating. In a second step, a second semi dense pattern of lines is printed in a second resist material layer provided over the cleared area. The first and second semi dense line patterns are positioned in interleaved position, to provide a desired dense pattern of lines and spaces. After development of the first resist material and before providing the second resist material to the substrate, a surface conditioning of the bottom anti-reflection coating is applied to the cleared area between lines of first resist material. The surface conditioning step is arranged to improve adhesion of a feature of second resist material to the surface of the cleared area.

This non-provisional application claims the benefit of and priority to U.S. Provisional Application No. 60/874,276, filed Dec. 12, 2006, the entire contents of which application is hereby incorporated by reference.

### FIELD

The present invention generally relates to lithography and associated methods and apparatus for exposing semiconductor substrates.

### BACKGROUND

Lithographic exposure apparatuses can be used, for example, in the manufacture of integrated circuits (ICs). In such a case, a patterning device may generate a circuit pattern corresponding to an individual layer of the IC. In photolithography, a beam of radiation is patterned by having that beam traverse the patterning device, and is projected by a projection system of the lithographic apparatus onto a target portion (e.g., comprising one or more dies) on a substrate (silicon wafer) that has been coated with a layer of photo-activated resist (i.e., photo resist) material, such as to image a desired pattern in the resist material. In general, a single substrate will contain a whole network of adjacent target portions that are successively irradiated via the projection system, one at a time.

In the semiconductor industry, the continual demand for smaller semiconductor devices, having smaller features in a layer of the IC, is pushing the task to print, on the substrate, patterns of densely arranged features such as gates and contacts. In particular there is a need to print patterns of dense lines and spaces. Printing such patterns involves at least two lithographic process steps. A first step involves optical imaging and resist material exposure to transfer a pattern from a patterning device (such as, for example, a mask or reticle provided with a mask pattern) to a resist material layer overlaying a substrate. A second process involves subjecting the exposed resist material layer to a development of resist material wherein either exposed or unexposed resist material portions of respectively positive tone or negative tone resist are dissolved, leaving resist material features protruding from the substrate. For example, dense lines and spaces can be printed using positive tone resist, so that lines consisting of unexposed, positive tone resist material are obtained.

Generally, a detrimental effect of reflection of exposure radiation at the substrate surface is alleviated by providing a bottom anti-reflection coating to the substrate before providing the resist material layer. Such a bottom anti-reflection coating is referred to as a BARC, hereinafter.

In a pattern of dense lines and spaces printed at best resolution, a line width CD (critical dimension) of the lines is substantially equal to the space width of the spaces, so that the line width is half of the pitch at which the lines are disposed in the pattern.

A maximum density at which lines can be printed is determined by lithographic apparatus characteristics as well as print-process characteristics. The apparatus characteristics include characteristics of the imaging system (e.g. the optical projection system) of the apparatus. The process characteristics include characteristics of the exposure and develop processes, and of the resist material.

Usually, the relation between the above mentioned characteristics and a smallest width CD of the lines or spaces arranged at maximum printable density is written as CD=k₁ (λ/NA), where NA represents the numerical aperture of the projection system, λ represents the wavelength of the exposure radiation, and k₁ is a factor representative of the effects of any of the characteristics other than NA and λ.

The above relation refers to a conventional single exposure lithographic printing process. For such a process, it is not possible to arrange the printing such that k₁<0.25, since the limit k₁=0.25 is a fundamental physical optical limit for printing dense line space structures.

Besides reducing wavelength and increasing numerical aperture, numerous so-called Resolution Enhancement Technologies (RET's) are in use or development to obtain an as low as possible value for k₁: examples of RET's are the use of mask-pattern assist features, the use of source-mask optimization calculations to identify optimal mask illumination schemes and related mask pattern layouts, and the use of different types of masks such as attenuated Phase Shifting Masks (PSM's) and alternating or chromeless PSM's.

To further increase the maximum density of dense line space patterns, a double patterning technique is proposed and developed which enables printing lines at k₁<0.25.

In, for example, a dual-trench double patterning process for printing dense lines and spaces, a first and a second pattern of spaces are etched, in interleaved position, in a target layer. The target layer may, for example, be a sacrificial etch mask to be used for an etching of a layer underlying the target layer. Such a double patterning technique exploits the possibility to print, in a single exposure process and for a given numerical aperture NA and wavelength λ, a semi-dense pattern of spaces at a width CD_{dp} below the value CD when the spaces are arranged at a pitch greater than 2k₁ (λ/NA). Thus, such a pattern is not a dense pattern in the sense that the widths of the lines and spaces are equal. Instead, a width of the lines is, for example, a factor three times the width CD_{dp} of the spaces. For printing such a semi dense pattern of line-shaped spaces or a semi dense pattern of trenches, wherein CD_{dp}<CD, generally a positive tone resist is used.

A dual-trench double patterning process for printing dense lines is characterized by the following three steps. In a first step, a first semi dense pattern of spaces is printed in resist material. After development of the resist material, the remaining resist material mask is used as etch mask for the second step. In the second step, the spaces are transferred to a target layer by applying an anisotropic etching process to the substrate, and the resist material mask is then stripped. Generally, a Reactive Ion Etching (RIE) process is used. In a third step, the target layer is again coated with resist material, and a second semi dense pattern of spaces is printed in the resist material. The second printing is arranged such that the spaces of the second pattern are positioned interleaved with respect to spaces etched in the target layer. As a result of the interleaving, a subsequent etching of the target layer, again using an RIE process, yields lines of target layer material protruding from the surface of the substrate. By interleaving two patterns of semi dense spaces, each pattern characterized by a space width CD_{dp} and a pitch 4 CD_{dp}, the resulting lines have a width equal to the space width CD_{dp}, so that a dense line pattern is obtained.

### SUMMARY

A problem associated with a dual-trench double patterning process as described above is that the RIE processing of a target layer between the first and second printing steps reduces the speed at which substrates can be patterned, and that a conventional lithographic apparatus or a conventional track apparatus (connected to the lithographic apparatus) does not include RIE processing means. A track apparatus is arranged to handle the substrate from and to the lithographic apparatus and to execute a plurality of resist material processing steps such as resist material coating, resist material development, and/or further standard pre- and post-exposure resist material processes such as a pre-exposure bake and/or a post-exposure bake.

It is desirable, for example, to provide a double patterning method wherein the detrimental effect of an etching process following a first patterning and preceding a second patterning are alleviated.

According to an aspect of the invention, there is provided a lithographic device manufacturing method comprising patterning a layer of a first radiation sensitive material, arranged to at least partially cover a surface of a substrate, with a pattern including a first and a second feature-segment protruding from the surface and separated by an uncovered portion of the surface, providing a layer of a second radiation sensitive material to the uncovered portion of the surface, patterning the layer of the second radiation sensitive material with a pattern including a third feature-segment, disposed in interleaved position with respect to the first and second feature-segments, protruding from the uncovered portion of the surface, and arranged to provide in combination with the first and second feature-segments a portion of a desired pattern, and applying a surface conditioning process to the uncovered portion of the surface, before providing the layer of the second radiation sensitive material and after patterning the layer of the first radiation sensitive material, to enhance adhesion of the third feature-segment to the surface.

According to an aspect of the invention, there is provided a lithographic cell comprising a lithographic apparatus, a plurality of process apparatus and a control unit configured to control both the lithographic apparatus and the process apparatus, wherein the plurality of process apparatus comprises a surface conditioning apparatus arranged to enhance adhesion to an uncovered portion of a surface of a substrate of a third feature-segment of a second radiation sensitive material, wherein the uncovered portion is disposed between a first and a second feature-segment of a first radiation sensitive material.

According to an aspect of the invention, there is provided a computer program product comprising instructions recorded on a computer readable medium, the instructions being adapted to control a lithographic cell to perform a device manufacturing method, the method including, in the order mentioned: providing a layer of a first radiation sensitive material on a surface of a substrate, patterning the layer with a pattern including a first and a second feature-segment protruding from the surface and separated by an uncovered portion of the surface, applying a surface conditioning process to the uncovered portion of the surface, to enhance an adhesion to the surface of a third feature-segment of a second radiation sensitive material, providing a layer of the second radiation sensitive material to the uncovered portion of the surface, patterning the layer of the second radiation sensitive material with a pattern including the third feature-segment disposed in interleaved position with respect to the first and second feature-segments and protruding from the uncovered portion of the surface and wherein the first, second and third feature-segments are arranged to provide in combination a portion of a desired pattern.

### BRIEF DESCRIPTION OF THE DRAWINGS

Embodiments of the invention will now be described, by way of example only, with reference to the accompanying schematic drawings in which corresponding reference symbols indicate corresponding parts, and in which:

FIG. 1 depicts a substrate provided with a resist material mask of line shaped features arranged as a dense line space pattern;

FIG. 2 depicts a flow diagram of steps which are part of a double patterning method in accordance with an embodiment of the invention;

FIG. 3A depicts a result of a printing of a first semi dense pattern of lines according to an embodiment of the invention;

FIG. 3B depicts a result of a printing of a second semi dense pattern of lines and positioned in interleaved position with respect to the first semi dense pattern of lines according to an embodiment of the invention;

FIG. 4 depicts a flow diagram of the double patterning method in accordance with an embodiment of the invention including a BARC surface conditioning step;

FIG. 5 depicts the result of a printing of a first semi dense pattern of lines as illustrated in FIG. 1, including portions of BARC surface affected by exposure to a first developer;

FIG. 6 depicts a substrate experimentally provided with a resist material mask of line shaped features arranged as a dense line space pattern and suffering from pattern collapse;

FIG. 7 depicts a substrate experimentally provided with a resist material mask of line shaped features arranged as a dense line space pattern in accordance with an embodiment of the present invention;

FIG. 8 depicts a lithographic apparatus connected to a device configured to condition a BARC surface, the device being part of a track apparatus, and

FIG. 9 depicts a lithographic apparatus according to an embodiment of the invention.

### DETAILED DESCRIPTION

### Embodiment 1

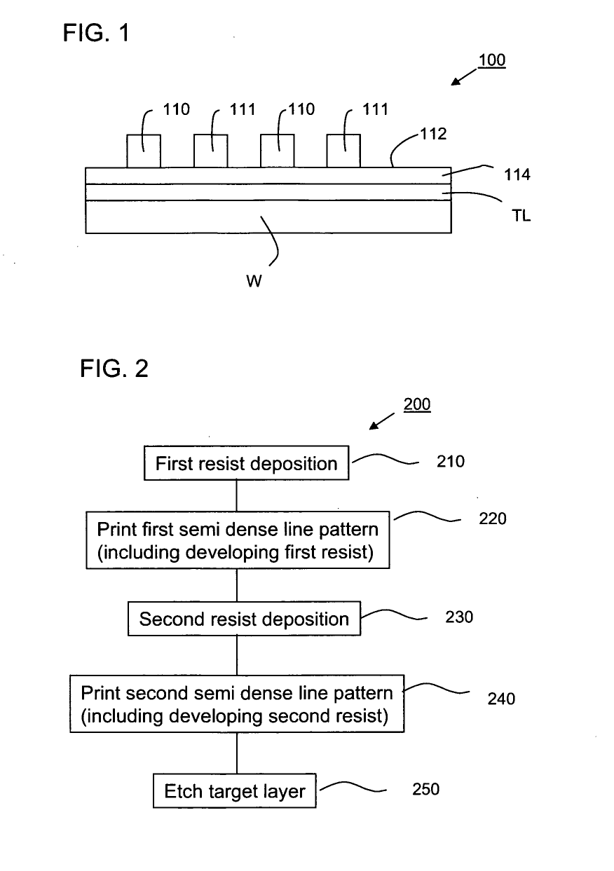

According to an embodiment of the invention, and as illustrated in FIG. 1, there is provided a dense line space pattern 100 of lines of resist material protruding from a surface 112 of a top layer 114. The top layer 114 may be a bottom anti-refection coating (BARC) at least partially overlaying a lithographic substrate W. The resist material of two adjacent lines 110 and 111 originates from two respective, separate, resist material depositions on the substrate. The first and second resist material depositions include providing and lithographically processing a respective first and second resist material to the substrate W. Each of the first and second resist material may be any radiation sensitive material such as, for example, positive tone resist or negative tone resist. The first and second resist material may be resists of opposite tonality. The lines 110 may be just feature-segments of one or more resist material features. Similarly, the lines 111 may be such segments. In an embodiment, the substrate is a silicon wafer, which may have been lithographically processed to provide one or more IC layers before applying the double patterning process of the present embodiment. The substrate is further provided with a target layer TL underneath the BARC layer 114, which is to be patterned with a desired pattern in accordance with the present method. The lines 110 and 111 may be just a portion of the desired pattern. The target layer TL may be an IC layer or any other type of layer for use in lithographic processing. Instead of a BARC, the top layer 114 may be, for example, an inorganic bottom anti-reflection coating, or a hard mask disposed on the substrate. The hard mask may, for example, be an oxide layer or a layer of a nitride such as SiON or SiN or TiN.

FIG. 2 illustrates a flow of process steps 200 which are part of the present double patterning method. After providing the first resist material to the substrate W (FIG. 2, step 210), a first semi dense line pattern is printed in the first resist material layer (FIG. 2, step 220). The printing includes a development step wherein a first developer is applied to provide a first set of spaces. A conventional hydroxide development process can be used for developing the first resist material. For example, a tetramethylammonium hydroxide solution is used in the present embodiment; this type of developer is usually referred to as a TMAH developer.

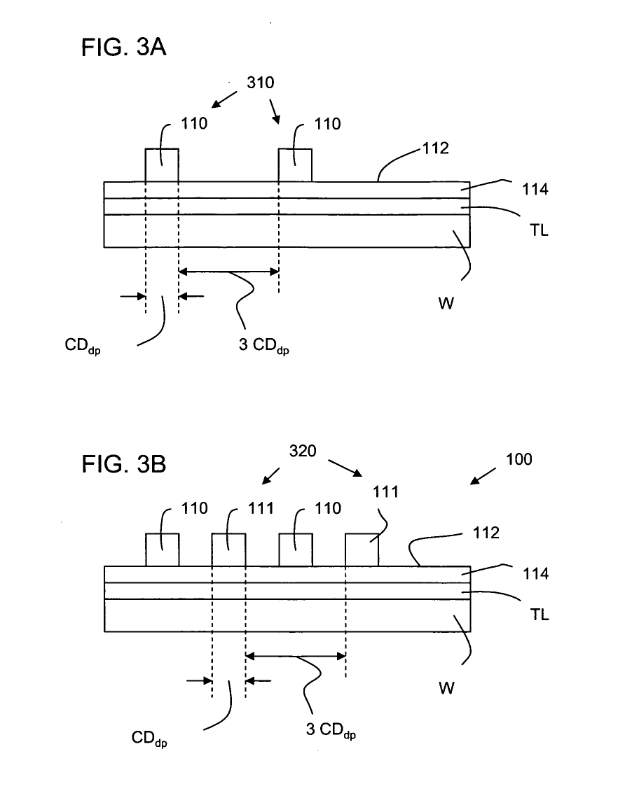

In FIG. 3A the result of the first two steps 210 and 220 is illustrated. The line width of the resulting first set of lines 310 protruding from the BARC surface is CD_{dp}, and the width of the spaces between the lines is 3 CD_{dp}. The two lines 110 in FIG. 3A may be just first and second feature-segments of one or more features.

Next, the second resist material is provided to the substrate (FIG. 2, step 230). This process is arranged such that at least the uncovered portions of the surface 112 (e.g. the spaces) between the first set of lines 310 are covered by or filled with second resist material. Further resist material pre-processing may be provided as well. Next a second semi dense line pattern 320 is printed in the second resist material layer (FIG. 2, step 240). The result of the steps 230 and 240 is illustrated in FIG. 3B. The second pattern is arranged such that the line width of the resulting second set of lines 320 protruding from the BARC surface 114 is CD_{dp} as well, and the width of the spaces between the lines 111 is 3 CD_{dp}. The position of the second set of lines 320 is arranged in interleaved position with respect to the first set of lines 310. This is schematically indicated in FIG. 3B. The line 111 between the two lines 110 in FIG. 3B may be just a third feature-segment between aforementioned first and second feature-segments of one or more features. The interleaving may be obtained, for example, by using first and second masks with patterns in accordance with respectively the first and second semi dense line patterns 310 and 320. The interleaving may then be obtained by disposing the two patterns mutually displaced with respect to one or more common alignment marks on the masks, and the displacement of the two patterns is chosen in accordance with the desired interleaving. The pitch of the resulting pattern is 2 CD_{dp}, and hence the desired dense line space pattern is obtained, where in view of CD_{dp} being smaller than CD, effectively the factor k₁ is or can be smaller than 0.25.

The second printing process (step 240) includes a development of the second resist material using a second developer, to provide a second set of spaces (i.e., the spaces between the lines 110 and 111 in FIG. 3B). The composition of the second developer and of the first resist material is arranged such that exposure to second developer of the first set of features 310 including lines 110 does not substantially affect the constitution and shape of these lines.

After the printing of the second semi dense line pattern 320, the desired etch mask pattern 100 of dense lines and spaces is obtained. A conventional RIE process can be applied to transfer the dense pattern of lines to the target layer TL (FIG. 2, step 250). The resist material mask can subsequently be stripped applying a conventional resist stripping process.

In the present embodiment, the first resist material is a positive tone photo resist, such as, for example TOK P6239 resist, and the first set of lines is printed using TMAH developer. An example patterning device that may be used for printing semi dense lines is a bright field mask such as, for example, a bright field chrome-on-glass mask (COG mask), an alternating Phase Shifting Mask (alternating PSM) or a chromeless PSM. The second resist material is a negative tone photo resist, such as for example TOK N023 or TOK N027 resist, and the second set of lines can be printed using, for example, a dark field COG mask, or a dark field attenuated PSM.

With reference to feature- and pattern-dimensions as obtained at the substrate level (e.g., to obtain the corresponding dimensions at patterning device level, one should account for the reduction ratio of the imaging by the projection system of the lithographic apparatus), lines of 50 nm width were imaged using two semi dense line patterns wherein the 50 nm lines were disposed at a pitch of 200 nm. By applying the method of the present embodiment, a resist material pattern of dense lines of 50 nm width and spaces of 50 nm width was obtained, using for each of the exposures a lithographic apparatus with NA=0.93 and λ=193 nm. The illumination setting was sigma=0.5, and COG mask patterns were used. The BARC was a AZ 1C5D BARC.

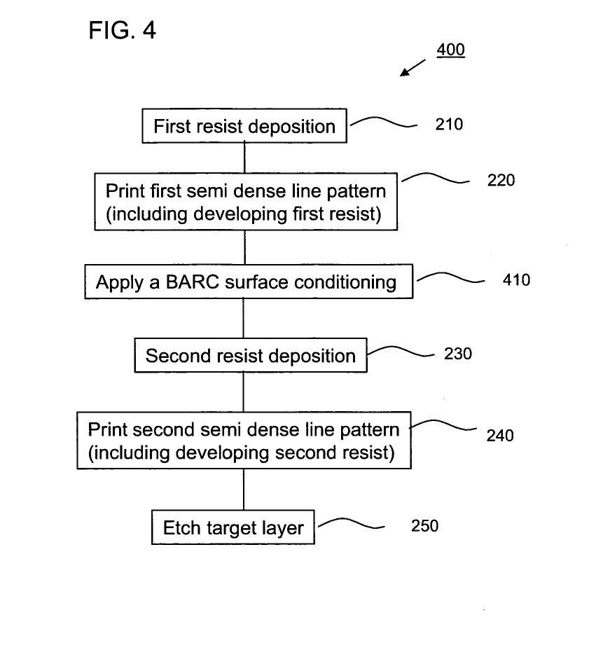

Although the present method can thus in principle be used for double patterning to avoid an intermediate RIE or other etch process, an improvement of the yield of the present double patterning process may be obtained by applying, after the first exposing and developing (i.e., after a first patterning of the first resist material layer) and before providing the second resist material to the substrate, a surface conditioning process step arranged to condition the cleared, uncovered portions of the surface 112 in between the features 110 in FIG. 3A. In the process flow 400 as illustrated in FIG. 4 this surface conditioning step is referred to in step 410. Compared to FIG. 2, the additional process step 410 is executed between the process step 220 of printing the first semi dense line pattern and the process step 230 of providing the second resist material to the substrate. Desirably, the surface conditioning step is to be applied after the first developing and before application, to the substrate, of the second resist material.

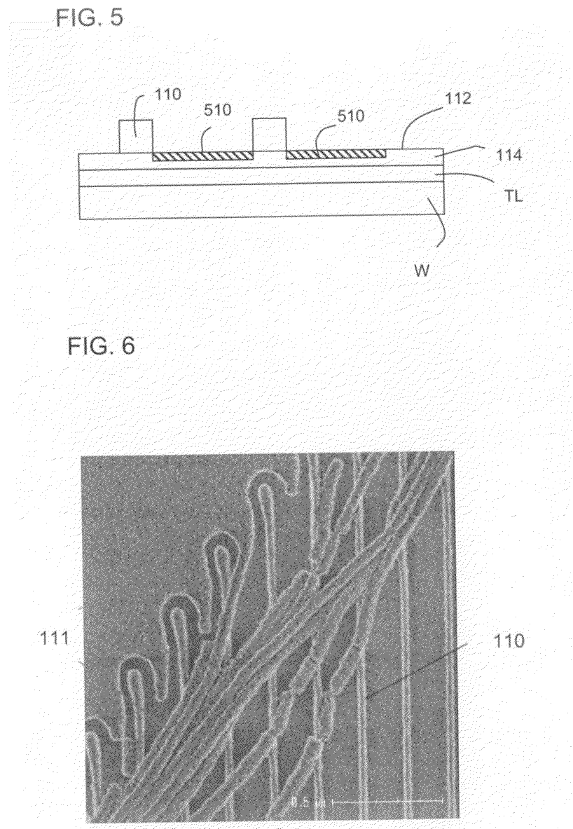

It is appreciated that during application of the TMAH developer (which is part of step 220 in FIG. 4) portions of the BARC surface 112 become uncovered upon dissolution of first resist material and get exposed to the TMAH developer. The surface of these uncovered BARC portions embody the surface of the spaces in FIG. 3A between the lines 110. The TMAH development process changes the properties of the BARC material of layer 114 proximate to and at the surface 112 of the uncovered BARC portions, as schematically indicated by the hatched surface portions 510 in FIG. 5. Exposure of the BARC surface to a TMAH developer changes the polarity and/or the acidity of the material included in the surface portions 510 of BARC. A higher polarity of the surface portion 510 is linked to a reduction of adhesion of a subsequently printed resist material feature to the underlying, developer-exposed BARC surface, and a lower acidity of the surface portion 510 is linked to causing an undercut (leading to reduced adhesion) of such a subsequently printed resist material feature beyond tolerance when using, as second resist material, a negative tone resist. The exposure of the BARC to TMAH developer is appreciated to cause an increase of polarity and/or a decrease of acidity. The BARC surface conditioning step 410 is arranged to fully or at least partly reduce the TMAH induced polarity increase and/or the TMAH induced acidity decrease. In the absence of the BARC surface conditioning step 410, a pattern collapse is likely to occur, due to reduced adhesion of the second resist material features to the BARC surface, and/or due to an undercut of the features of the second resist material. An example of a pattern collapse is illustrated in FIG. 6. This detrimental effect can be avoided by arranging the BARC surface conditioning step 410 to affect the polarity and/or the acidity (expressed in units pH) of the BARC surface portions 510.

In the present embodiment, and according to an aspect of the present invention, the BARC surface conditioning step 410 includes exposing the substrate to an acid, which may be a hydrofluoric acid or an acetic acid. For example, the substrate may be subjected to a hydrofluoric (HF) spray processing. Such a processing can be executed using an acid spraying device, which may be part of the track system. An effect of exposure of the substrate to an acid spray, such as for example a HF acid spray, is that hydrophilic hydroxyl groups are replaced by hydrophobic fluorine groups and that the acidity of the BARC areas 510 is increased.

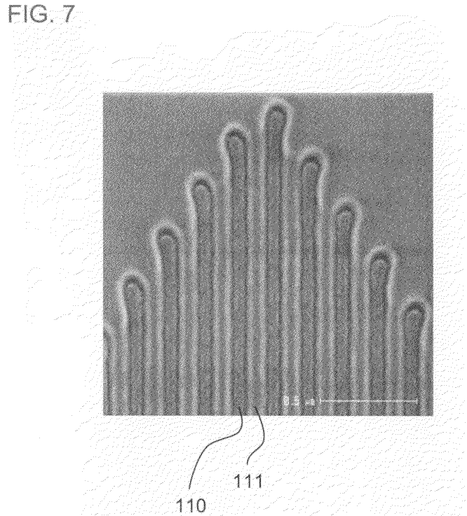

A result obtained in the present embodiment is shown in FIG. 7.

### Second Embodiment

A second embodiment is the same as the first embodiment save that the BARC surface conditioning step 410 includes exposing the substrate to a fluorocarbon based plasma or a hydrogen-containing fluorocarbon based plasma. For example, a CxHyFz plasma treatment also has the effect of replacing hydrophilic hydroxyl groups by hydrophobic fluorine groups. The BARC surface conditioning steps of the first and second embodiments may be used in combination.

### Third Embodiment

A third embodiment is the same as the first embodiment save that in addition to the BARC surface conditioning step 410 the method further includes a fixation step arranged to further reduce possible detrimental impact of subsequent processing steps (such as for example any one of the steps 410, 230 and 240) on the features 110 of first resist material. The fixation step may for example include a hard baking of the substrate, after patterning the layer of first resist material and before providing the layer of second resist material, at a temperature sufficiently high to cause at least some flow of material in the line features 110 of the first semi dense line pattern. Desirably, the hard bake is executed at a temperature of 200 degrees K or higher. The BARC surface conditioning steps of the first and second embodiments may each be used in combination with the hard bake step of the present embodiment.

It is appreciated that another effect of the hard bake is to further deactivate photo-active components of the remaining first resist material; such residual photo active components may have a detrimental effect when activated during the second exposure. Another or alternative advantage of the hard bake step is that it reduces the residual solubility of the first resist material features 110 in the second developer; a further dissolving of the lines 110 could occur during the development step of the second resist material.

An advantage of any of the present embodiments is that, during the second exposure, only the resist material portions corresponding to the lines 111 in FIG. 3B are exposed, so that scattering of exposure radiation at the line shaped resist material features 110 is substantially avoided. This may cause an optimal contrast of the image, in the second resist material, of the second semi dense line pattern.

According to an aspect of the present invention, each of the BARC surface conditioning steps is combined with a conventional method to prevent pattern collapse, such as applying a rinse liquid and/or using a super critical carbon dioxide developer.

### Fourth Embodiment

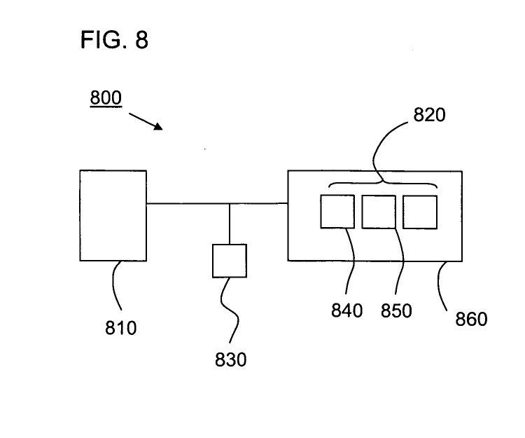

In a fourth embodiment, and as illustrated in FIG. 8, there is provided a lithographic cell 800 comprising a lithographic projection apparatus 810, a plurality of process apparatus 820 and a control unit 830 configured to control both the lithographic apparatus and the process apparatus, wherein the plurality of process apparatus comprises a surface conditioning apparatus 840 arranged to enhance adhesion of a resist material feature-segment to an uncovered portion of a surface of a substrate, the uncovered portion of the surface being disposed between a first and a second feature-segment of a first radiation sensitive material, and the resist material feature-segment being a feature-segment of a third radiation sensitive material. The lithographic projection apparatus 810 is combined with a device 840 constructed and arranged to condition a BARC surface in accordance with any of the methods described above. The device 840 may be part of a track apparatus 860, connected to the lithographic projection apparatus 810, arranged to handle and transport a substrate from and to the lithographic apparatus and to execute resist material processing such as spin coating, resist material development, and/or further standard pre- and post-exposure resist material processes such as a pre-exposure bake and/or post-exposure bake.

The surface conditioning apparatus 840 of the lithographic cell 800 may be connected to a supply 850 of acid, such as for example hydrofluoric acid or acetic acid. Alternatively or additionally, the surface conditioning apparatus 840 may be arranged to expose the substrate to a fluorocarbon based plasma or a hydrogen-containing fluorocarbon based plasma, in which case the supply 850 refers to a mechanism to supply an etch gas. In the present embodiment, the surface conditioning apparatus 840 is included in the track 860 connected to and for use with the lithographic projection apparatus 810.

The control unit 830 comprises a storage medium having stored therein instructions to cause the lithographic cell 800 to perform a method including, in the order mentioned, providing a layer of a first resist or radiation sensitive material on a surface 112 of a layer 114 (such as a BARC) on the substrate W, patterning the layer of first resist material with a pattern 310 including a first and a second feature-segment protruding from the surface 112 and separated by an uncovered portion of the surface 112, applying a surface conditioning process 410 to the uncovered portion of the surface 112, to enhance an adhesion to the surface 112 of a layer of a second resist or radiation sensitive material, providing the layer of the second resist material to the uncovered portion of the surface 112, patterning the layer of the second resist material with a pattern including a third feature-segment disposed in interleaved position with respect to the first and second feature-segments and protruding from the uncovered portion of the surface 112 and wherein the first, second and third feature-segments are arranged to provide in combination a portion of a desired pattern. The first and second feature-segments may be segments of line shaped features 110, and the third feature-segment may be a segment of one line of line shaped feature 111.

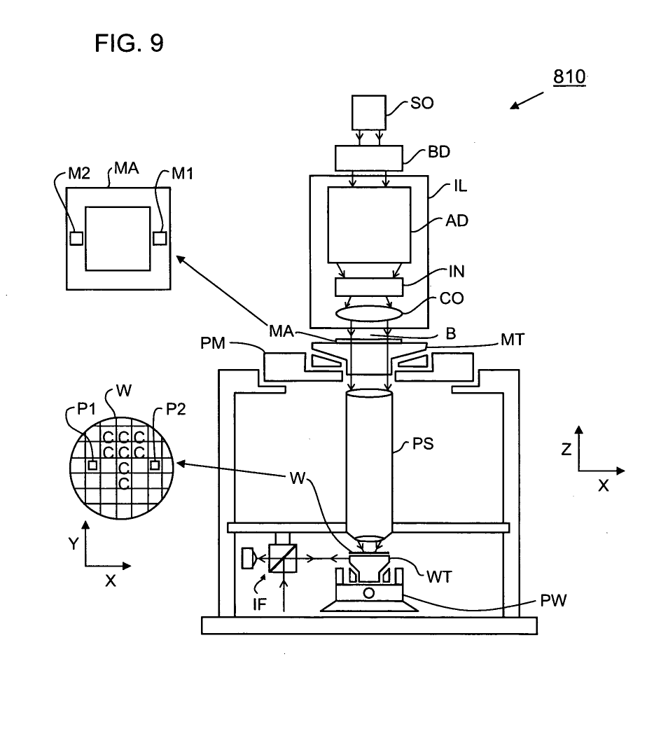

FIG. 9 schematically depicts a lithographic apparatus 810 according to an embodiment of the invention. The apparatus comprises:

an illumination system (illuminator) IL configured to condition a radiation beam B (e.g. UV radiation and DUV radiation such as for example generated by an excimer laser operating at a wavelength of 193 nm or 248 nm, or EUV radiation such as for example generated by a laser-fired plasma source operating at 13.6 nm);

a support structure (e.g. a mask table) MT constructed to support a patterning device (e.g. a mask) MA and connected to a first positioner PM configured to accurately position the patterning device in accordance with certain parameters;

a substrate table (e.g. a wafer table) WT constructed to hold a substrate (e.g. a resist-coated wafer) W and connected to a second positioner PW configured to accurately position the substrate in accordance with certain parameters; and

a projection system (e.g. a refractive projection lens system) PS configured to project a pattern imparted to the radiation beam B by patterning device MA onto a target portion C (e.g. comprising one or more dies) of the substrate W.

The illumination system may include various types of optical components, such as refractive, reflective, magnetic, electromagnetic, electrostatic or other types of optical components, or any combination thereof, for directing, shaping, or controlling radiation.

The support structure MT holds the patterning device in a manner that depends on the orientation of the patterning device, the design of the lithographic apparatus, and other conditions, such as for example whether or not the patterning device is held in a vacuum environment. The support structure can use mechanical, vacuum, electrostatic or other clamping techniques to hold the patterning device. The support structure may be a frame or a table, for example, which may be fixed or movable as required. The support structure may ensure that the patterning device is at a desired position, for example with respect to the projection system. Any use of the terms “reticle” or “mask” herein may be considered synonymous with the more general term “patterning device.”

The term “patterning device” used herein should be broadly interpreted as referring to any device that can be used to impart a radiation beam with a pattern in its cross-section such as to create a pattern in a target portion of the substrate. It should be noted that the pattern imparted to the radiation beam may not exactly correspond to the desired pattern in the target portion of the substrate, for example if the pattern includes phase-shifting features or so called assist features. Generally, the pattern imparted to the radiation beam will correspond to a particular functional layer in a device being created in the target portion, such as an integrated circuit.

The patterning device may be transmissive or reflective. Examples of patterning devices include masks, programmable mirror arrays, and programmable LCD panels. Masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted so as to reflect an incoming radiation beam in different directions. The tilted mirrors impart a pattern in a radiation beam which is reflected by the mirror matrix.

The term “projection system” used herein should be broadly interpreted as encompassing any type of projection system, including refractive, reflective, catadioptric, magnetic, electromagnetic and electrostatic optical systems, or any combination thereof, as appropriate for the exposure radiation being used, or for other factors such as the use of an immersion liquid or the use of a vacuum. Any use of the term “projection lens” herein may be considered as synonymous with the more general term “projection system”.

As here depicted, the apparatus is of a transmissive type (e.g. employing a transmissive mask). Alternatively, the apparatus may be of a reflective type (e.g. employing a programmable mirror array of a type as referred to above, or employing a reflective mask).

The lithographic apparatus may be of a type having two (dual stage) or more substrate tables (and/or two or more patterning device tables). In such “multiple stage” machines the additional tables may be used in parallel, or preparatory steps may be carried out on one or more tables while one or more other tables are being used for exposure.

The lithographic apparatus may also be of a type wherein at least a portion of the substrate may be covered by a liquid having a relatively high refractive index, e.g. water, so as to fill a space between the projection system and the substrate. An immersion liquid may also be applied to other spaces in the lithographic apparatus, for example, between the mask and the projection system. Immersion techniques are well known in the art for increasing the numerical aperture of projection systems. The term “immersion” as used herein does not mean that a structure, such as a substrate, must be submerged in liquid, but rather only means that liquid is located between the projection system and the substrate during exposure.

Referring to FIG. 9, the illuminator IL receives a radiation beam from a radiation source SO. The source and the lithographic apparatus may be separate entities, for example when the source is an excimer laser. In such cases, the source is not considered to form part of the lithographic apparatus and the radiation beam is passed from the source SO to the illuminator IL with the aid of a beam delivery system BD comprising, for example, suitable directing mirrors and/or a beam expander. In other cases the source may be an integral part of the lithographic apparatus, for example when the source is a mercury lamp. The source SO and the illuminator IL, together with the beam delivery system BD if required, may be referred to as a radiation system.

The illuminator IL may comprise an adjuster AD for adjusting the angular intensity distribution of the radiation beam. Generally, at least the outer and/or inner radial extent (commonly referred to as σ-outer and σ-inner, respectively) of the intensity distribution in a pupil plane of the illuminator can be adjusted. In addition, the illuminator IL may comprise various other components, such as an integrator IN and a condenser CO. The illuminator may be used to condition the radiation beam, to have a desired uniformity and intensity distribution in its cross-section.

The radiation beam B is incident on the patterning device (e.g., mask) MA, which is held on the support structure (e.g., mask table) MT, and is patterned by the patterning device. Having traversed the patterning device MA, the radiation beam B passes through the projection system PS, which focuses the beam onto a target portion C of the substrate W. With the aid of the second positioner PW and position sensor IF (e.g. an interferometric device, linear encoder or capacitive sensor), the substrate table WT can be moved accurately, e.g. so as to position different target portions C in the path of the radiation beam B. Similarly, the first positioner PM and another position sensor (which is not explicitly depicted in FIG. 9) can be used to accurately position the patterning device MA with respect to the path of the radiation beam B, e.g. after mechanical retrieval from a mask library, or during a scan. In general, movement of the support structure MT may be realized with the aid of a long-stroke module (coarse positioning) and a short-stroke module (fine positioning), which form part of the first positioner PM. Similarly, movement of the substrate table WT may be realized using a long-stroke module and a short-stroke module, which form part of the second positioner PW. In the case of a stepper (as opposed to a scanner) the support structure MT may be connected to a short-stroke actuator only, or may be fixed. Patterning device MA and substrate W may be aligned using patterning device alignment marks M1, M2 and substrate alignment marks P1, P2. Although the substrate alignment marks as illustrated occupy dedicated target portions, they may be located in spaces between target portions (these are known as scribe-lane alignment marks). Similarly, in situations in which more than one die is provided on the patterning device MA, the patterning device alignment marks may be located between the dies.

The depicted apparatus could be used in at least one of the following modes:

1. In step mode, the support structure MT and the substrate table WT are kept essentially stationary, while an entire pattern imparted to the radiation beam is projected onto a target portion C at one time (i.e. a single static exposure). The substrate table WT is then shifted in the X and/or Y direction so that a different target portion C can be exposed. In step mode, the maximum size of the exposure field limits the size of the target portion C imaged in a single static exposure.

2. In scan mode, the support structure MT and the substrate table WT are scanned synchronously while a pattern imparted to the radiation beam is projected onto a target portion C (i.e. a single dynamic exposure). The velocity and direction of the substrate table WT relative to the support structure MT may be determined by the (de-)magnification and image reversal characteristics of the projection system PS. In scan mode, the maximum size of the exposure field limits the width (in the non-scanning direction) of the target portion in a single dynamic exposure, whereas the length of the scanning motion determines the height (in the scanning direction) of the target portion.

3. In another mode, the support structure MT is kept essentially stationary holding a programmable patterning device, and the substrate table WT is moved or scanned while a pattern imparted to the radiation beam is projected onto a target portion C. In this mode, generally a pulsed radiation source is employed and the programmable patterning device is updated as required after each movement of the substrate table WT or in between successive radiation pulses during a scan. This mode of operation can be readily applied to maskless lithography that utilizes programmable patterning device, such as a programmable mirror array of a type as referred to above.

Combinations and/or variations on the above described modes of use or entirely different modes of use may also be employed.

As will be appreciated, in any of the embodiments described above any reference to lines and spaces herein may be generalized to features and gaps between such features.

In any of the embodiments described above it is desirable to achieve a uniform distribution (over the area of the desired pattern) of a desired width of interleaved features and a desired width of resulting gaps between interleaved features. For example, for the printing of a dense line space pattern (characterized by a desired line width and a desired space width CD_{dp}) at different locations in a die, it is desirable to achieve a uniform distribution over the die area of the printed line and space widths. In an embodiment, a first and a second mask with patterns in accordance with respectively the first and second semi dense line patterns 310 and 320 may be used to obtain the interleaving. The two patterns are positioned with respect to one or more common (equivalent) alignment marks on the masks, such that, relative to the common alignment marks, positions of features on one mask are well correlated with positions of features on the other mask. However, the providing of the desirable correlation of feature positions between the two masks may cause errors in the width of lines to occur at the same positions relative to the alignment marks, for example because the two mask patterns were written or printed using a same tool, and with a short time-interval in between. This results in areas in which all neighboring printed lines have a width larger than nominal width (referred to as thick lines) and other areas in which all neighboring printed lines have a width smaller than nominal width. Similar printed line width errors may be due to systematic variations of an imaging parameter of the imaging apparatus and/or a systematic variation of exposure dose across the imaging field or target portion.

For areas in which all lines have a larger than nominal width, there can be a higher occurrence of short-circuiting between lines upon completing the double patterning process by the provision of interleaved lines. In order to reduce the risk of short-circuiting in areas with thick lines, the lines to be interleaved, during the second exposure, are desirably printed as lines with a width smaller than nominal width. By using a resist with a different tonality in the second exposure step, as in any of the embodiments, a CD response (i.e., a deviation of printed line width in response to size errors of mask pattern features and/or to printing process errors) is reversed with respect to the first exposure, resulting in a substantial reduction of the probability of short-circuiting.

Although specific reference may be made in this text to the use of lithographic apparatus in the manufacture of ICs, it should be understood that the lithographic apparatus described herein may have other applications, such as the manufacture of integrated optical systems, guidance and detection patterns for magnetic domain memories, flat-panel displays, liquid-crystal displays (LCDs), thin-film magnetic heads, etc. The skilled artisan will appreciate that, in the context of such alternative applications, any use of the terms “wafer” or “die” herein may be considered as synonymous with the more general terms “substrate” or “target portion”, respectively. The substrate referred to herein may be processed, before or after exposure, in for example a track (a tool that typically applies a layer of resist to a substrate and develops the exposed resist), a metrology tool and/or an inspection tool. Where applicable, the disclosure herein may be applied to such and other substrate processing tools. Further, the substrate may be processed more than once, for example in order to create a multi-layer IC, so that the term substrate used herein may also refer to a substrate that already contains multiple processed layers.

Although specific reference may have been made above to the use of embodiments of the invention in the context of optical lithography, it will be appreciated that the invention may be used in other applications, and where the context allows, is not limited to optical lithography.

The lithographic apparatus may also be of a type wherein a surface of the substrate is immersed in a liquid having a relatively high refractive index, e.g. water, so as to fill a space between a final element of the projection system and the substrate. Immersion liquids may also be applied to other spaces in the lithographic apparatus, for example, between the patterning device and a first element of the projection system. Immersion techniques are well known in the art for increasing the numerical aperture of projection systems.

The terms “radiation” and “beam” used herein encompass all types of electromagnetic radiation, including ultraviolet (UV) radiation (e.g. having a wavelength of or about 365, 248, 193, 157 or 126 nm) and extreme ultra-violet (EUV) radiation (e.g. having a wavelength in the range of 5-20 nm).

While specific embodiments of the invention have been described above, it will be appreciated that the invention may be practiced otherwise than as described. In any of the embodiments, instead of the layer 114 being a BARC, the top layer 114 may be, for example, an inorganic bottom anti-reflection coating, or a hard mask disposed on the substrate. A hard mask may, for example, be an oxide layer or a layer of a nitride such as SiON or SiN or TiN. It is appreciated that the developer used to develop the first radiation sensitive material is a basic solution. The layer 114 may be of any material that is sensitive to the developer having the properties of a base.

An embodiment of the invention may take the form of a computer program containing one or more sequences of machine-readable instructions describing a method as disclosed above, or a data storage medium (e.g. semiconductor memory, magnetic or optical disk) having such a computer program stored therein. In particular, according to an embodiment of the invention, there is provided a computer program product comprising instructions recorded on a computer readable medium, the instructions being adapted to control the lithographic cell 800 to perform a device manufacturing method, the method including, in the order mentioned: providing a layer of a first radiation sensitive material on a surface 112 of a substrate W, patterning the layer with a pattern 310 including a first and a second feature-segment protruding from the surface and separated by an uncovered portion of the surface 112, applying a surface conditioning process 410 to the uncovered portion of the surface, to enhance an adhesion to the surface of a third feature-segment of a second radiation sensitive material, providing a layer of the second radiation sensitive material to the uncovered portion of the surface, patterning the layer of the second radiation sensitive material with a pattern 320 including the third feature-segment disposed in interleaved position with respect to the first and second feature-segments and protruding from the uncovered portion of the surface 112 and wherein the first, second and third feature-segments are arranged to provide in combination a portion of a desired pattern.

The descriptions above are intended to be illustrative, not limiting, Thus, it will be apparent to those skilled in the art that modifications may be made to the invention as described without departing from the scope of the claims set out below.

1. A lithographic device manufacturing method, comprising:
patterning a layer of a first radiation sensitive material, arranged to at least partially cover a surface of a substrate, with a pattern including a first and a second feature-segment protruding from the surface and separated by an uncovered portion of the surface;
providing a layer of a second radiation sensitive material to the uncovered portion of the surface;
patterning the layer of the second radiation sensitive material with a pattern including a third feature-segment, disposed in interleaved position with respect to the first and second feature-segments, protruding from the uncovered portion of the surface, and arranged to provide in combination with the first and second feature-segments a portion of a desired pattern; and
applying a surface conditioning process to the uncovered portion of the surface, before providing the layer of the second radiation sensitive material and after patterning the layer of the first radiation sensitive material, to enhance adhesion of the third feature-segment to the surface.

2. The method of claim 1, wherein the surface conditioning process is arranged to change a polarity, an acidity, or a polarity and an acidity of the uncovered portion of the surface.

3. The method of claim 2, wherein the surface conditioning process comprises exposing the substrate to an acid.

4. The method of claim 3, wherein the acid comprises hydrofluoric acid or acetic acid.

5. The method of claim 2, wherein the surface conditioning process comprises exposing the substrate to a fluorocarbon based plasma or a hydrogen-containing fluorocarbon based plasma.

6. The method of claim 1, wherein the surface is a surface of a bottom anti-reflection coating, an inorganic bottom anti-reflection coating, or a hard mask disposed on the substrate.

7. The method of claim 1, wherein the second radiation sensitive material has a tonality opposite to a tonality of the first radiation sensitive material.

8. The method of claim 1, wherein the first radiation sensitive material has a positive tonality and the second radiation sensitive material has a negative tonality.

9. The method of claim 1, further comprising exposing the substrate to a hard bake before providing the layer of the second radiation sensitive material and after patterning the layer of the first radiation sensitive material.

10. The method of claim 9, wherein the hard bake is executed at a temperature higher than 200 degrees K.

11. A lithographic cell comprising a lithographic apparatus, a plurality of process apparatus and a control unit configured to control both the lithographic apparatus and the process apparatus, wherein the plurality of process apparatus comprises a surface conditioning apparatus arranged to enhance adhesion to an uncovered portion of a surface of a substrate of a third feature-segment of a second radiation sensitive material, wherein the uncovered portion is disposed between a first and a second feature-segment of a first radiation sensitive material.

12. The lithographic cell of claim 11, wherein the surface conditioning apparatus is connected to a supply of acid, hydrofluoric acid, or acetic acid.

13. The lithographic cell of claim 11, wherein the surface conditioning apparatus is arranged to expose a substrate to a fluorocarbon based plasma or a hydrogen-containing fluorocarbon based plasma.

14. The lithographic cell of claim 11, wherein the surface conditioning apparatus is included in a track connected to and for use with the lithographic projection apparatus.

15. The lithographic cell of claim 11, wherein the control unit comprises a storage medium having stored therein instructions to cause the lithographic cell to perform a method including, in the order mentioned:
providing a layer of a first radiation sensitive material on a surface of a substrate;
patterning the layer with a pattern including a first and a second feature-segment protruding from the surface and separated by an uncovered portion of the surface;
applying a surface conditioning process to the uncovered portion of the surface, to enhance an adhesion to the surface of a third feature-segment of a second radiation sensitive material;
providing a layer of the second radiation sensitive material to the uncovered portion of the surface; and
patterning the layer of the second radiation sensitive material with a pattern including the third feature-segment disposed in interleaved position with respect to the first and second feature-segments and protruding from the uncovered portion of the surface and wherein the first, second and third feature-segments are arranged to provide in combination a portion of a desired pattern.

16. The lithographic cell of claim 15, wherein the second radiation sensitive material has a tonality opposite to a tonality of the first radiation sensitive material.

17. A computer program product comprising instructions recorded on a computer readable medium, the instructions being adapted to control a lithographic cell to perform a device manufacturing method, the method including, in the order mentioned:
providing a layer of a first radiation sensitive material on a surface of a substrate;
patterning the layer with a pattern including a first and a second feature-segment protruding from the surface and separated by an uncovered portion of the surface;
applying a surface conditioning process to the uncovered portion of the surface, to enhance an adhesion to the surface of a third feature-segment of a second radiation sensitive material;
providing a layer of the second radiation sensitive material to the uncovered portion of the surface;
patterning the layer of the second radiation sensitive material with a pattern including the third feature-segment disposed in interleaved position with respect to the first and second feature-segments and protruding from the uncovered portion of the surface and wherein the first, second and third feature-segments are arranged to provide in combination a portion of a desired pattern.

18. The computer program product of claim 17, wherein the surface conditioning process comprises changing a polarity, an acidity, or a polarity and an acidity of the uncovered portion of the surface.

19. The computer program product of claim 18, wherein the surface conditioning process comprises exposing the substrate to an acid.

20. The computer program product of claim 19, wherein the acid comprises hydrofluoric acid or acetic acid.

21. The computer program product of claim 18, wherein the surface conditioning process comprises exposing the substrate to a fluorocarbon based plasma or a hydrogen-containing fluorocarbon based plasma.

22. The computer program product of claim 17, wherein the second radiation sensitive material has a tonality opposite to a tonality of the first radiation sensitive material.

23. The computer program product of claim 17, further comprising exposing the substrate to a hard bake before providing the layer of the second radiation sensitive material and after patterning the layer of the first radiation sensitive material.
